(19) United States
(12) Patent Application Publication
(10) Pub. No.: US 2020/0047326 A1
(43) Pub. Date: Feb. 13, 2020

(54) SYSTEM METHOD AND APPARATUS FOR FOREIGN OBJECT DAMAGE (FOD) PREVENTION

(71) Applicant: Alexandru Barbayanni, West Nyack, NY (US)

(72) Inventor: Alexandru Barbayanni, West Nyack, NY (US)

(21) Appl. No.: 16/538,125

(22) Filed: Aug. 12, 2019

Related U.S. Application Data
(60) Provisional application No. 62/717,373, filed on Aug. 10, 2018.

(51) Int. Cl. B25H 3/00; H05K 13/04; H04W 4/029

(52) U.S. Cl. CPC B25H 3/00; H04W 4/029; H05K 13/0413

(57) ABSTRACT

A foreign object damage (FOD) prevention system utilizing a plurality of RFID chips attached to a tool to detect misplaced or detached components from each particular tool. Reverse triangulation accountability (RTA) incorporates a reader and an object to be ranged and vectored (positioned accurately) by use of two radio transmitters completing a triangle. The system may also facilitate location of a misplaced undamaged tool.

### CROSS-REFERENCE TO RELATED APPLICATION

This application claims the benefit of priority of U.S. provisional application No. 62/717,373, filed Aug. 10, 2018, the contents of which are herein incorporated by reference.

### BACKGROUND OF THE INVENTION

The present invention relates to foreign object damage (FOD), and more particularly to systems, methods, and apparatus for preventing FOD.

In aviation and other heavy equipment operations FOD remains a significant issue. From maintenance areas, parking aprons, taxiways, runways, and even in the inflight environment, FOD can threaten the safety of the aircraft, aircrews, ground personnel and missions. Within the maintenance environment, FOD dangers arise in the form of lost or misplaced tools and even repair parts, either those left within the airframe or around engine intakes and landing gear.

Many systems have been developed to assist and remedy these hazards. They typically involve inventory control and inspection regimens to identify when a tool or part goes missing following a maintenance procedure. While these systems go a long way towards reducing the incidence of FOD mishaps, they do not address the hidden costs, such as aborted missions and man hour intensive searches associated with a lost tool.

These lost tools require massive searches in order to avoid putting machinery and lives at risk. The search usually results in increased man-hours, a total halt in operations and even damage to equipment or loss of life. Examples would be a lost tool on an airport tarmac. Such a lost tool must be found before any aircraft can start its engines and proceed to take-off. These searches usually involve all personnel, and do not cease until the tool is found.

As can be seen, there is a need for an improved system, method, and apparatus for FOD prevention that facilitates locating a missing tool or part.

### SUMMARY OF THE INVENTION

In one aspect of the present invention, a system for preventing a foreign object damage (FOD) hazard by a tracked article, such as a tool or a component is disclosed. The system includes a first tracking chip and a second tracking chip attached to the tracked article and separated by a reference chip spacing. A transmitter/receiver is configured to determine a range between the receiver/transmitter and each of the first tracking chip and the second tracking chip. A control logic circuit is configured to determine a chip separation distance between the first tracking chip and the second tracking chip. An alert notification is configured to activate when the range exceeds a detection range limit of the transmitter/receiver.

In some embodiments, a reference database store the reference chip spacing for each of a plurality of tracked articles. The control logic circuit may be configured to determine when the chip separation distance does not match the reference chip spacing. The alert notification may activate when the chip separation distance does not match the reference chip spacing.

In certain embodiments, the control logic circuit determines a separation angle between the first tracking chip and the second tracking chip, relative to the transmitter receiver. The chip separation distance may be determined based on the separation angle and the range.

In some embodiments, the alert is selected from one of an audible, a visual, or a vibratory alert based on an operational environment of the system.

In other aspects of the invention, a method for preventing foreign object damage (FOD) by a tracked article is disclosed. The method includes attaching a first tracking chip and a second tracking chip to the tracked article. A reference chip spacing between the first tracking chip and the second tracking chip is recorded. A transmitter/receiver that is configured to determine a range between the receiver/transmitter and each of the first tracking chip and the second tracking chip is activated. A control logic circuit may then determine a chip separation distance between the first tracking chip and the second tracking chip.

In some embodiments of the method an alert may be activated when the range exceeds a detection range limit of the transmitter/receiver.

In other embodiments a disparity between the reference chip spacing and the chip separation distance is detected. When the disparity is detected an alert may then be activated.

In other embodiments, an error correction value may be applied to the disparity before activating the alert.

In yet other embodiment, a separation angle is determined between the first tracking chip and the second tracking chip and the chip separation distance is determined based on the range between each of the first tracking chip and the second tracking chip and the separation angle.

These and other features, aspects and advantages of the present invention will become better understood with reference to the following drawings, description and claims.

### BRIEF DESCRIPTION OF THE DRAWINGS

FIG. 1 is a schematic diagram illustrating a first condition for a tracked article that is accounted for with the FOD prevention system.

FIG. 2 is a schematic diagram illustrating an alternate condition for a tracked article that is accounted for with the FOD prevention system.

FIG. 3 is a schematic diagram illustrating a first condition for a tracked article that is unaccounted for with the FOD prevention system.

FIG. 4 is a schematic diagram illustrating a first alternate condition for a tracked article that is unaccounted for with the FOD prevention system.

FIG. 5 is a schematic diagram illustrating a second alternate condition for a tracked article that is unaccounted for with the FOD prevention system.

FIG. 6 illustrates is a schematic diagram illustrating a third alternate condition for a tracked article that is unaccounted for with the FOD prevention system.

FIG. 7a illustrates a desired tracking chip spacing on a tool when compared to a reference chip spacing.

FIG. 7b illustrates a first tracking chip disparity condition where the first tracking chip is too close to the second tracking chip relative to a reference chip spacing.

FIG. 7c illustrates a second tracking chip disparity where the first tracking chip is too far from the second tracking chip relative to a reference chip spacing.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

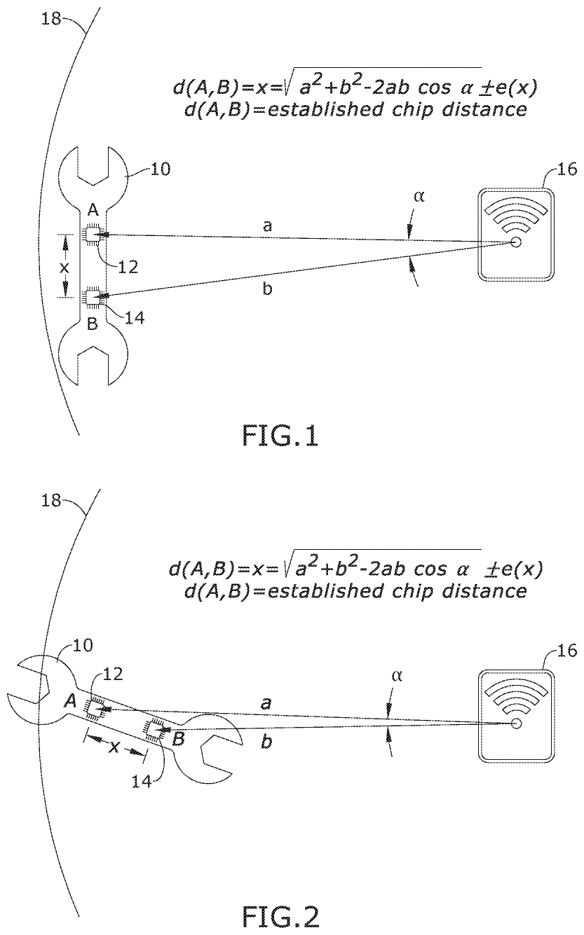

Broadly, embodiments of the present invention provide an improved system, method, and apparatus for FOD prevention that facilitates locating a tracked article, such as a missing tool, a part, or tracking a component assigned to said tool or part. As seen in reference to the drawings of FIGS. 1-7, the present invention includes a plurality of tracking chips 12, 14, such as a radio frequency identification device (RFID) that is applied to a tracked article 10, such as tool or component, used in the performance of maintenance activities. A transmitter/receiver 16 is configured to detect each of the plurality of tracking chips 12, 14 and is configured with a logic circuit to implement a reverse triangulation accountability (RTA) process according to aspects of the invention.

The RTA is a process similar to simple radio triangulation—where an object is ranged and vectored (positioned accurately) by use of two radio transmitters/receivers with the object to be detected completing a triangle. The variation in radio frequencies phases will give the position of the object. The RTA employs a geometrically similar concept, where triangulation is used, but with only one transmitter/receiver and two transmitters affixed on the object 10 that needs to be detected.

The RTA, according to aspects of the present invention, eliminates the risks associated with typical tool and equipment inventory systems, in critical environments, such as aircraft maintenance. Most tracking systems present a higher FOD risk by the very chip used to track them. By adding an additional distinct chip and using reverse triangulation, continuous monitoring ensures that the tool as well as all of its tracking components are always located and cannot end up in a FOD situation.

The RTA, according to the present invention, prevents the main problem with conventional tool tracking systems where, each tool is fitted with a chip (RFID, GPS, etc.) to combat lost or misplaced tools. However, in the event where the chip detaches from the tool itself, a chip reader may still consider that particular tool as accounted for, when in fact, only the chip is within reading range but the tool is not physically present. Every moment where a tool is unaccounted for is an additional risk to aircraft on the ground or already airborne.

According to aspects of the present invention, each individual tool 10 is equipped with two distinct chips 12, 14. A tool 10 that is accounted for, must be within a detection range limit 18 of the transmitter/receiver 16. This means that the transmitter/receiver 16 has detected both chips 12, 14 associated with that particular tool 14 and has determined them to be affixed to said tool 10 at a reference chip spacing X. The reference chip spacing X is measured after the initial installation of the chips 12 and 14 on the tool 10 and is kept in a reference database to check against future readings.

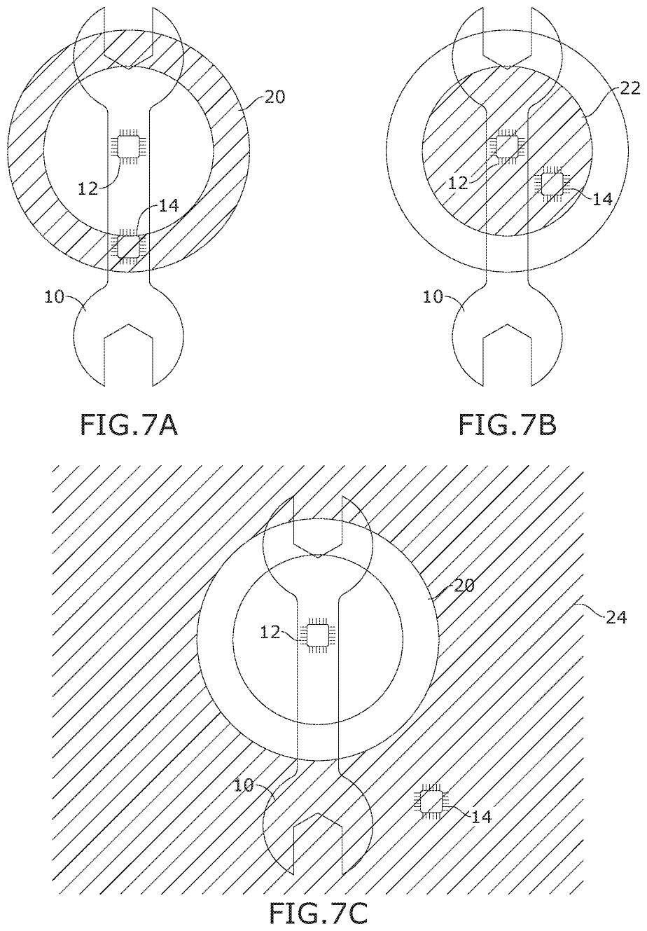

Simply put, detecting one chip, say chip A 12, then chip B 14 must be within the reference chip spacing from chip A, as in FIG. 7a. The drawing represents the space between two spheres, one of a radius representing the minimum distance chip B 14 can be from chip A 12, and the other of radius representing the maximum distance B 14 can be from A 12. FIG. 7b and FIG. 7c show chip B 14 too close to chip A 12, then too far respectively, which means one of the chips 12, 14 had detached from the tool 10.

The RTA uses a process that is impossible to achieve with a single chip, as there is no third point in a single chip system to complete a triangle in the reverse-triangulation process. The means by which the transmitter/receiver determines that chips A 12 and B 14 are still affixed to their appropriate tool is as follows:

The transmitter/receiver 16 ranges each chip 12, 14 to determine a separation range of the chips 12, 14 from the transmitter/receiver 16. In other words the transmitter/receiver 16 calculates how far chips A 12 and B 14 are in relation to itself. These values are a and b shown in FIG. 1 and FIG. 2.

The control logic associated with the transmitter/receiver 16 then determines a separation angle α (alpha) in between the arriving signals from chips A 12 and B 14.

The control logic may then determine a chip separation distance X′ between chips A 12 and B 14 labeled X′ in FIG. 1 and FIG. 2, by using the cosine law (the square of side X′ of a triangle is equal to the sum or squares of the other sides (a, b) minus 2 times the product of a, b and cosine of the angle α between a and b).

In some embodiments, a preset error function e(x) may be added to take into account variations in air density or other interference. The transmitter/receiver 16 compares the value of the chip separation distance X′ from its calculation to the reference chip spacing X from the database. If the chip separation distance X′ is within a set range specified by e(x) then the tool 10 still has both chips 12, 14 affixed properly.

If during the course of work, one of the chips 12, 14 becomes detached, such as shown in reference to FIG. 3, the transmitter/receiver 16 will perform the same steps in calculating the chip separation distance X′ based on the distances (a, b) and angle (a) established above. The final value for the chip separation distance X′ would greatly differ from the reference chip spacing X, either larger or smaller (although probabilistically it will be greater). This would indicate that a chip 12, 14 has detached from the tool 10. One or more types of alerts are issued (aural, visual, vibrate) selected based on an operating environment, prompting immediate action to be taken in order to prevent the detached chip from becoming a FOD hazard.

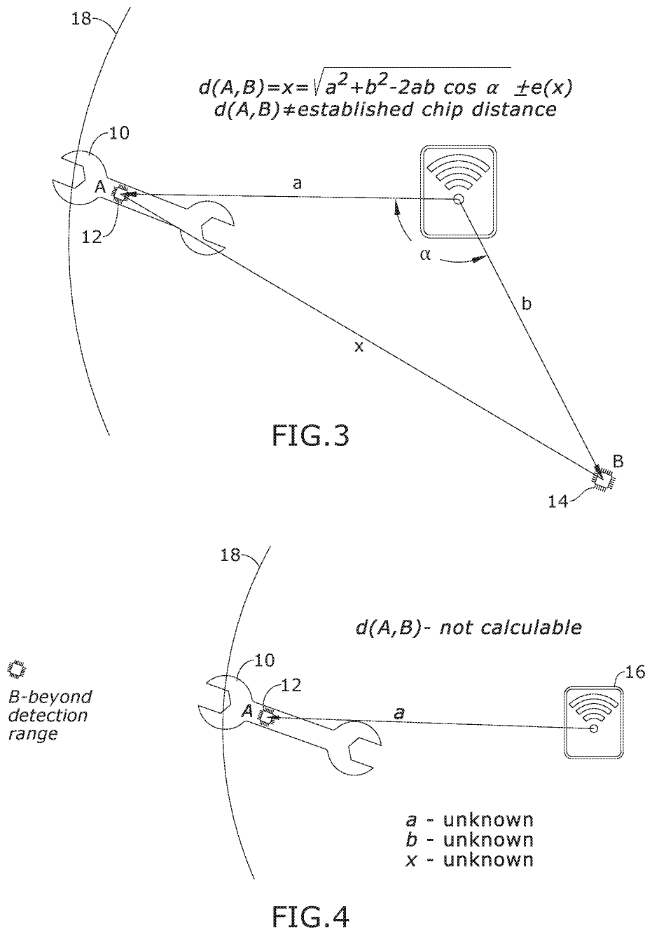

If the transmitter/receiver 16 cannot detect the detached chip, as shown in reference to FIG. 4, then the transmitter/receiver 16 cannot reverse triangulate using both chips 12, 14. Despite not having a value for the chip separation distance X to compare against the reference chip spacing X, the transmitter/receiver 16 will assume the undetected chip B 14 has detached and issue the appropriate alerts.

Upon receiving an alert, personnel will initiate a search of the immediate area (usually a quick search) for the detached chip 14 by moving the transmitter/receiver 16. The transmitter/receiver 16 movement will also move the detection range limit 18 accordingly, until chip B 14 is within range as in FIG. 3 allowing the detached chip 14 to be located and retrieved.

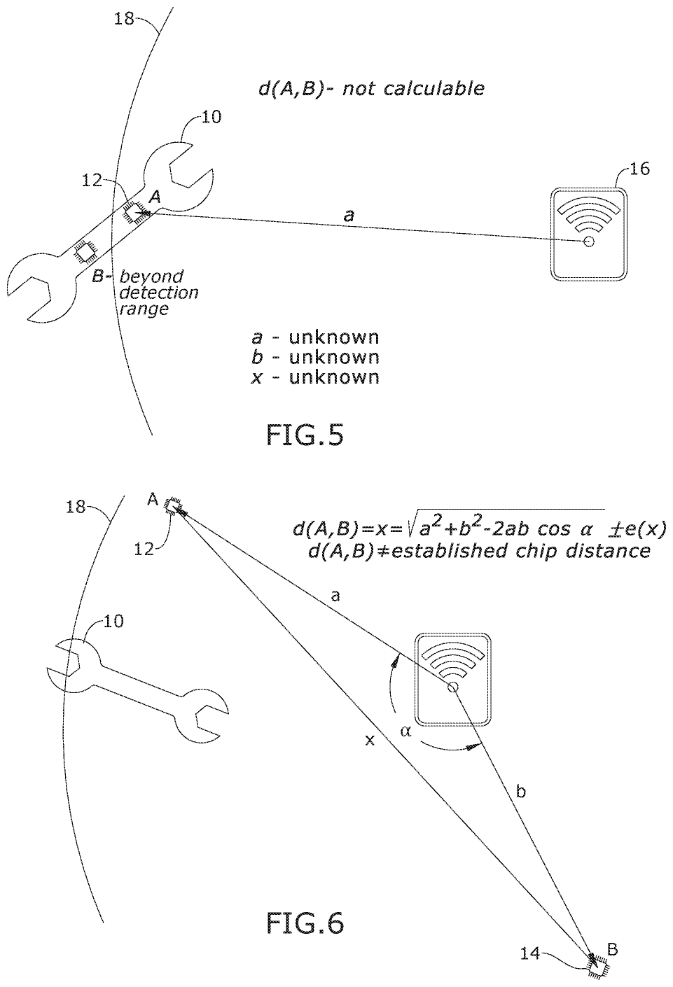

Once detecting the missing chip 14, the transmitter/receiver 16 will alert the user of the tool 10 or any other personnel within the chain of command (supervisors, etc.) with the appropriate alert. Similarly, if a tool 10 is at the detection range limit 18, as in FIG. 5, the transmitter/receiver will issue the same alert as mentioned above. Since it cannot detect chip B 14 it will assume it has detached from the tool 10 (it will assume the worst case scenario, a detached chip). However, once the transmitter/receiver 16 moves in closer proximity so that chip B 14 which initially was beyond the detection range, is now detected, the transmitter/receiver 16 will be able to perform its normal calculation of the chip separation distance X′ and see that the tool 10 has both chips A 12 and B 14 affixed properly.

FIG. 6 covers the highly unlikely event that both chips A 12 and B 14 detach from the tool 10. In this event, the transmitter/receiver 16 will calculate the chip separation X′ as it changes in real time, detecting an increasing value.

The function of the increase of the chip separation X′ can be estimated based on how fast a chip falls due to gravity, relative to the normal speed and acceleration of a tool 10 that is in normal use. As such, the transmitter/receiver 16 can calculate that one chip is accelerating under gravitational acceleration (i.e. falling) and the other is not. This would be the case of FIG. 3, before chip B has hit the ground and stopped any motion.

If both chips 12, 14 detach, both chips A 12 and B 14 will be detected as having acceleration, but at different speeds. If the tool 10 falls with the chips affixed, both A 12 and B 14 will be detected with the same acceleration, and the same instant velocity. If chips A 12 and B 14 detached, they will have different velocities, based on when each chip begins to fall. This may be utilized as a first indicator to the transmitter/receiver 16 that a two chip detachment has occurred, and an alarm is issued to alert the user of this condition. This is the rarest occurrence, and is highly improbably from a practical stand point, however it is the most dangerous, since the tool 10 would have no chip to track it, increasing its chance of becoming FOD. By measuring the acceleration and velocities of chips A 12 and B 14, and their differences, the transmitter/receiver 16 can detect a two chip detachment instantly.

The RTA eliminates the risks associated with typical tool and equipment inventory systems, in critical environments. Most tracking systems present a higher FOD risk by the very chip used to track them. By adding an additional distinct chip and using reverse triangulation, continuous monitoring ensures that the tool 10 as well as all of its tracking components are always located and cannot end up in a FOD situation.

The system of the present invention may include at least one computer with a user interface. The computer may include any computer including, but not limited to, a desktop, laptop, and smart device, such as, a tablet and smart phone. The computer includes a program product including a machine-readable program code for causing, when executed, the computer to perform steps. The program product may include software which may either be loaded onto the computer or accessed by the computer. The loaded software may include an application on a smart device. The software may be accessed by the computer using a web browser. The computer may access the software via the web browser using the internet, extranet, intranet, host server, internet cloud and the like.

The computer-based data processing system and method described above is for purposes of example only, and may be implemented in any type of computer system or programming or processing environment, or in a computer program, alone or in conjunction with hardware. The present invention may also be implemented in software stored on a non-transitory computer-readable medium and executed as a computer program on a general purpose or special purpose computer. For clarity, only those aspects of the system germane to the invention are described, and product details well known in the art are omitted. For the same reason, the computer hardware is not described in further detail. It should thus be understood that the invention is not limited to any specific computer language, program, or computer. It is further contemplated that the present invention may be run on a stand-alone computer system, or may be run from a server computer system that can be accessed by a plurality of client computer systems interconnected over an intranet network, or that is accessible to clients over the Internet. In addition, many embodiments of the present invention have application to a wide range of industries. To the extent the present application discloses a system, the method implemented by that system, as well as software stored on a computer-readable medium and executed as a computer program to perform the method on a general purpose or special purpose computer, are within the scope of the present invention. Further, to the extent the present application discloses a method, a system of apparatuses configured to implement the method are within the scope of the present invention.

It should be understood, of course, that the foregoing relates to exemplary embodiments of the invention and that modifications may be made without departing from the spirit and scope of the invention as set forth in the following claims.

What is claimed is:

1. A system for preventing a foreign object damage (FOD) hazard of a tracked article, comprising:
a first tracking chip and a second tracking chip attached to the tracked article and separated by a reference chip spacing;
a transmitter/receiver configured to determine a range between the transmitter/receiver and the first tracking chip and the second tracking chip;
a control logic circuit configured to determine a chip separation distance between the first tracking chip and the second tracking chip; and
an alert notification configured to activate when the range exceeds a detection range limit of the transmitter/receiver.

2. The system of claim 1, further comprising:
a reference database storing the reference chip spacing for each of a plurality of tracked articles.

3. The system of claim 1, wherein the control logic circuit is configured to determine when the chip separation distance does not match the reference chip spacing.

4. The system of claim 3, wherein the alert notification is configured to activate when the chip separation distance does not match the reference chip spacing.

5. The system of claim 3, wherein the control logic circuit determines a separation angle between the first tracking chip and the second tracking chip, relative to the transmitter/receiver.

6. The system of claim 5, wherein the control logic circuit determines the chip separation distance based on the separation angle.

7. The system of claim 1, wherein the alert notification is selected from an audible, visual, or vibratory alert selected for an operational environment of the system.

8. A method for preventing foreign object damage (FOD) by a tracked article, comprising:
attaching a first tracking chip and a second tracking chip to the tracked article;
recording a reference chip spacing between the first tracking chip and the second tracking chip;
activating a transmitter/receiver configured to determine a range between the transmitter/receiver and each of the first tracking chip and the second tracking chip; and
determining, by a control logic circuit, a chip separation distance between the first tracking chip and the second tracking chip.

9. The method of claim 8, further comprising:
activating an alert when the range exceeds a detection range limit of the transmitter/receiver.

10. The method of claim 8, further comprising:
detecting a disparity between the reference chip spacing and the chip separation distance; and
activating an alert when a disparity between the reference chip spacing and the chip separation distance is detected.

11. The method of claim 10, further comprising:
applying an error correction value to the disparity before activating the alert.

12. The method of claim 10, further comprising:
determining a separation angle between the first tracking chip and the second tracking chip, and
determining the chip separation distance based on the range between each of the first tracking chip and the second tracking chip and the separation angle.
